(19) United States
(12) Patent Application Publication
(10) Pub. No.: US 2007/0045660 A1
(43) Pub. Date: Mar. 1, 2007

(54) Heterojunction structure of nitride semiconductor and nano-device or an array thereof comprising same

(75) Inventors: Gyu Chul Yi, Pohang-si (KR); Sung-Jin An, Pohang-si (KR)

Correspondence Address: David A. Einhorn, Esq.;Anderson Kill & Olick, P.C., 1251 Avenue of the Americas, New York, NY, 10020, US

(73) Assignee: POSTECH FOUNDATION

(21) Appl. No.: 11/411,557

(22) Filed: Apr. 25, 2006

Related U.S. Application Data
(62) Division of application No. 10/971,488, filed on Oct. 22, 2004, now abandoned.

(30) Foreign Application Priority Data
Dec. 2, 2004 (KR) 2004-0009263

(51) Int. Cl. H01L 29/732

(52) U.S. Cl. 257/183

(57) ABSTRACT

A heterojunction structure composed of a nitride semiconductor thin film and nanostructures epitaxially grown thereon exhibits high luminescence efficiency property due to facilitated tunneling of electrons through the nano-sized junction, and thus can be advantageously used in light emitting devices.

### FIELD OF THE INVENTION

The present invention relates to a novel heterojunction structure comprising a nitride semiconductor film and a nanostructure epitaxially grown thereon, which provides nano-devices having improved luminescence properties.

### BACKGROUND OF THE INVENTION

The Gallium nitride (GaN)-based blue light emitting diode (LED) developed by Nichia Chemical Co., Ltd. in 1992 uses a GaN p-n thin film junction to provide blue and green LED devices, and in 1997, a short wavelength (404 nm) blue LED having a life span of about 10,000 hours at room temperature has been developed using a nitride semiconductor.

Such light emitting devices, however, comprise a gallium nitride in the form of a thin film deposited on a sapphire substrate which requires a high manufacturing cost and gives a relatively low luminescence efficiency.

### SUMMARY OF THE INVENTION

Accordingly, it is an object of the present invention to provide a novel nitride-based structure which can be formed on a substrate other than sapphire and facilitates electron tunneling, thereby making it possible to provide nitride semiconductor-based nano-devices having high light-emission properties at a low cost.

It is another object of the present invention to provide a nano-device or an array thereof comprising such a structure.

In accordance with one aspect of the present invention, there is provided a nitride semiconductor-based heterojunction structure composed of a nitride semiconductor thin film and a nitride nanostructure epitaxially grown thereon.

In accordance with another aspect of the present invention, there is provided a nano-device or an array thereof comprising said heterojunction structure.

### BRIEF DESCRIPTION OF THE DRAWINGS

The above and other objects and features of the present invention will become apparent from the following description of the invention, when taken in conjunction with the accompanying drawings, which respectively show:

FIGS. 1a, 1b and 1c: schematic diagrams of the light emitting diode devices comprising heterojunction structures in accordance with the present invention;

FIGS. 2a, 2b and 2c: electron microscope scans of the GaN-based p-n heterojunction structures obtained in Examples 1 and 2 of the present invention; and

FIG. 3: the light emission spectrum of the LED obtained in Example 2 of the present invention, which comprises the heterojunction structure formed by epitaxially growing n-type GaN nanostructures on a p-type GaN thin film.

### DETAILED DESCRIPTION OF THE INVENTION

The inventive heterojunction structure is characterized by comprising a nitride semiconductor thin film and a nitride nanostructure epitaxially grown thereon.

Also, a nano-device comprising said heterojunction structure can be fabricated by forming electrodes using a thermal or electron beam evaporation technique on the opposing surfaces of the nitride semiconductor thin film and nanostructures of the heterojunction structure.

The semiconductor types of the nitride thin film and nanostructures grown thereon are selected to form a p-n or n-p type heterojunction structure.

In the inventive heterojunction structure, the nitride semiconductor thin film may be in the form of a single crystal, or a thin film formed on a substrate such as sapphire, Al₂O₃, silicon (Si), glass, quartz, silicon carbide (SiC) plate, etc., using a conventional metal organic chemical vapor deposition (MOCVD) method which comprises heating a substrate and bringing the vapors of appropriate precursors of a nitride into contact with the surface of the substrate under a subambient pressure.

In the present invention, an inexpensive and readily processible material such as silicon, glass, etc. can be used as a substrate in place of a nonconductive sapphire substrate which is hard to process and has a small size of 2 in² or less, which makes it possible to mass-produce a nitride based structure on a large area at a low cost.

The nitride semiconductor thin film of the inventive structure may have a thickness ranging from 50 nm to 200 μm.

Representative examples of the nitride semiconductor material for a thin film are GaN, AlN, InN, and a nitrogen compound containing GaN, AlN, InN or a mixture thereof; and preferred is GaN.

Further, the nitride semiconductor nanostructure grown on the nitride thin film may be a nitride semiconductor nanorod, nanotube, or core-shell nanostructure having a shell coating of a nitride material such as GaN, InGaN, AlGaN, etc. Examples of the core-shell nanostructure are a nitride-coated ZnO-nanorod such as a GaN/ZnO nanorod, from which a nanotube can be obtained by removing the ZnO core therefrom.

The nanostructures may be epitaxially grown onto a nitride semiconductor thin film using a conventional metal organic chemical vapor deposition (MOCVD) method which comprises bringing the vapors of metal organic precursors into contact with the surface of a thin film, or using a molecular beam epitaxy (MBE) method which comprises irradiating an ion beam on a target so that the target material can be grown on a thin film, as is well known in the art.

The nanostructure formed on a thin film may have a diameter in the range of 5 nm to 1 μm (not inclusive) and a length in the range of 5 nm to 100 μm.

The nitride semiconductor thin film and nanostructures may each be obtained in a desired form by controlling reaction conditions such as the amount of gaseous reactants introduced into a reaction chamber, deposition temperature and time, etc., during their growth.

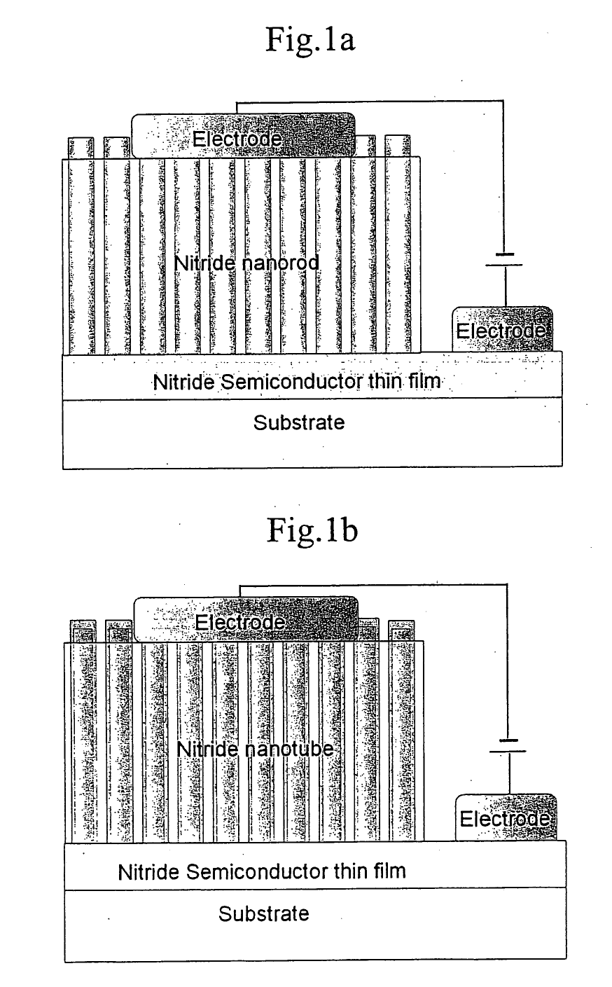

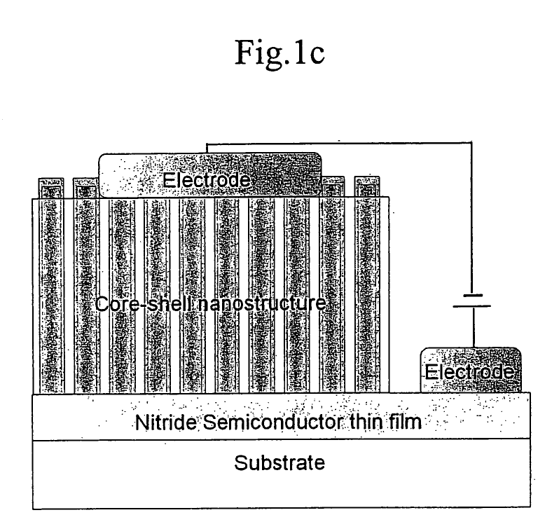

The inventive heterojunction structure composed of a nitride semiconductor thin film and nanostructures such as nanorods, nanotubes and core-shell nanorods vertically grown thereon can be used for LED devices as shown in FIGS. 1a, 1b and 1c, respectively.

The heterojunction structure according to the present invention may be a p-n or n-p nano junction which facilitates electron tunneling to increase the light emission area, and thus can be used for LED or a display having high luminescence efficiency at room temperature or higher.

Also, since one-dimensional nitride nanomaterials are formed epitaxially on a thin film in the inventive heterojunction structure, an array of LED comprising the structure can be easily assembled to fabricate various nanosystems or integrated circuits.

The following Examples are intended to illustrate the present invention more specifically, without limiting the scope of the invention.

### EXAMPLE 1

### The Growth of Core-Shell Nanostructures on a Nitride Semiconductor Thin Film

An Mg-doped GaN thin film was deposited on an Al₂O₃ substrate using a conventional MOCVD technique and annealed, to obtain a p-type GaN thin film having a thickness of 2 μm. The metal organic precursors used were trimethylgallium (TMGa) and bis(cyclopentadienyl) magnesium ((C₅H₅)₂Mg); and the nitrogen precursor, NH₃.

Then, n-type ZnO nanorods were vertically grown on the p-type GaN thin film thus obtained, by an MOCVD technique using diethylzinc (Zn(C₂H₅)₂) and O₂ with an argon (Ar) carrier gas. The reactor pressure and temperature were maintained in the ranges of 0.1 to 1,000 torr and 200 to 1,000° C., respectively, during one hour nanorod growth time.

After the completion of the growth of the n-ZnO nanorods on the p-GaN thin film, n-GaN was coated on the surface of the n-ZnO nanorods by injecting gaseous TMGa and NH₃ into the reactor and reacting the vapors for 1 to 30 minutes, to obtain an n-p heterojunction structure comprising n-GaN/n-ZnO nanorods having a shell/core structure grown on the p-GaN thin film. The reactor pressure and temperature were kept in the ranges of 0 to 760 torr and 400 to 700° C., respectively, during the GaN coating.

When p-type nanorods were desired, p-type doping was performed by adding (C₅H₅)₂Mg to the above n-type nanorod growth condition.

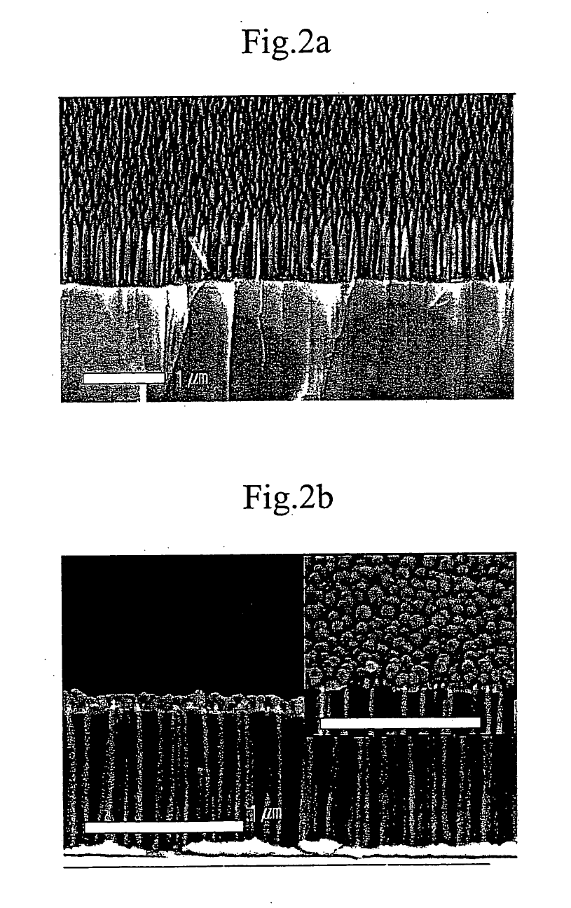

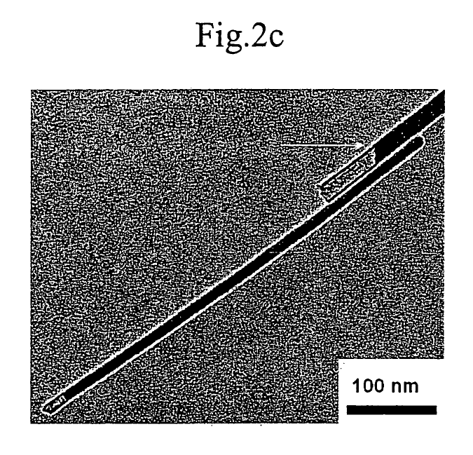

A scanning electron microscope (SEM) photograph of the n-p heterojunction structure thus obtained, n-GaN/n-ZnO nanorods grown on a p-GaN thin film, is shown in FIG. 2a. As shown in FIG. 2a, GaN/ZnO nanorods having a 40 nm diameter and 1 μm length were uniformly and vertically grown on the surface of the GaN thin film. Further, an X-ray diffraction (XRD) study showed that the nanorods are epitaxially grown in the (0001) orientation on the GaN thin film substrate having the same orientation.

Subsequently, the removal of the ZnO core portion of GaN/ZnO nanorods was carried out by injecting H₂ or NH₃ at a flow rate in the range from 100 to 2,000 sccm into the reactor, while maintaining the reactor pressure and temperature in the ranges of 10-5 to 760 mmHg and 400 to 900° C., respectively, to obtain a heterojunction structure comprising n-GaN nanotubes grown on a p-GaN thin film.

### EXAMPLE 2

### Fabrication of a Light Emitting Device

Light emitting diodes were fabricated using the heterojunction structures prepared in Example 1 as follows.

First, the free space around the nanostructures, GaN/ZnO nanorods or GaN nanotubes, grown on a GaN thin film, was filled up by depositing an insulating material thereon, and then, the tip portion of the nanostructures was exposed by etching using a plasma. Subsequently, a Ti (10 nm)/Au (50 nm) top ohmic electrode was formed at the tip portion of the etched n-type nanostructures; and a Pt (10 nm)/Au (50 nm) bottom electrode, on the p-type GaN thin film, by a thermal or electron beam evaporation technique. The applied accelerating voltage and emission current were in the ranges of 4 to 20 kV and 40 to 400 mA, respectively, during the electrodes deposition, while keeping the reactor pressure at around 10-5 mmHg, and the substrate temperature at room temperature.

The cross-sectional morphology of the top electrode-formed GaN/ZnO nanorods was investigated by scanning electron microscopy (SEM) and the result is shown in FIG. 2b; and a transmission electron microscope (TEM) photograph of the GaN/ZnO nanorods in the heterojuncion structure is shown in FIG. 2c.

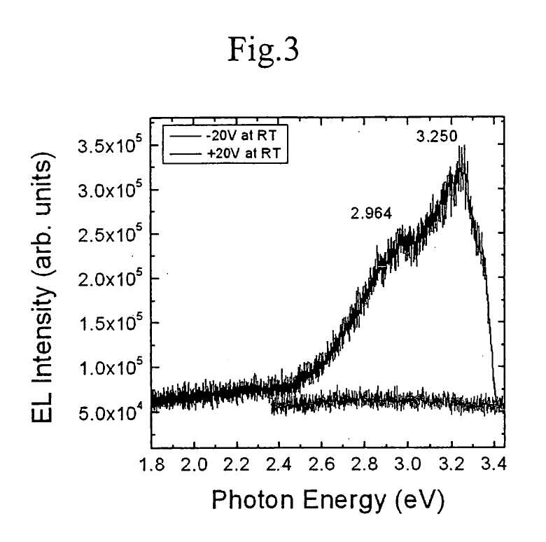

Also, a light emission spectrum of the LED thus obtained is shown in FIG. 3. The light emission was strong enough to be visually recognizable and its intensity did not decrease during a long period (several tens of cycles) of repeated operation. Further, as shown in FIG. 3, the device has emission peaks at around 3.25 eV and 2.96 eV.

The above result suggests that the inventive heterojunction structure of a nitride semiconductor thin film having epitaxially grown nanostructures has an excellent light emission property.

While the embodiments of the subject invention have been described and illustrated, it is obvious that various changes and modifications can be made therein without departing from the spirit of the present invention which should be limited only by the scope of the appended claims.

1. A process for preparing a heterojunction structure comprising forming a nitride semiconductor thin film and directly growing a nitride nanostructure epitaxially thereon.

2. (canceled)

3. The process of claim 1, wherein the nitride semiconductor thin film is in the form of a single crystal, or is formed on a substrate selected from the group consisting of a sapphire, Al₂O₃, silicon (Si), glass, quartz and silicon carbide (SiC) plate.

4. The process of claim 1, wherein the nitride semiconductor thin film has a thickness ranging from 50 nm to 200 μm.

5. The process of claim 1, wherein the nanostructure is a nitride nanorod or nanotube having a diameter in the range of 5 nm to 1 μm (not inclusive) and a length in the range of 5 nm to 100 μm.

6. The process of claim 1, wherein the nitride semiconductor and the nitride nanostructure are each independently made of a material selected from the group consisting of GaN, AlN, InN, and a nitrogen compound containing GaN, AlN, InN or a mixture thereof.

7. (canceled)

8. (canceled)
